(19) United States
(12) Patent Application Publication
(10) Pub. No.: US 2008/0021634 A1
(43) Pub. Date: Jan. 24, 2008

(54) Latch apparatus for portable electronic devices

(76) Inventor: Melvin Bernard Diaz, La Palma, CA (US)

Correspondence Address: MURAMATSU & ASSOCIATES, Suite 310, 114 Pacifica, Irvine, CA, 92618, US

(21) Appl. No.: 11/640,615

(22) Filed: Dec. 18, 2006

Related U.S. Application Data
(60) Provisional application No. 60/754,247, filed on Dec. 27, 2005.
(60) Provisional application No. 60/754,240, filed on Dec. 27, 2005.

(51) Int. Cl. H05K 7/00; G01C 21/00

(52) U.S. Cl. 701/200; 361/679

(57) ABSTRACT

The latch apparatus for portable display devices has a pin portion and an actuator. The latch apparatus has an opening into which the pin portion is inserted to secure the display device in a device mount. The actuator applies force to release the pin to remove the display device from the device mount. Both the actuator and the pin portion have ramps that are designed to make contact with each other and slide as force is exerted to the actuator. Due to the ramps, the pin portion moves to withdraw from the opening of the display device as force is applied to the actuator. Biasing means maintains the position of the pin such that the pin portion securely holds the display device in the device mount unless the actuator is pressed for releasing the pin portion.

This application claims the benefit of U.S. Provisional Application No. 60/754,240 filed Dec. 27, 2005.

### FIELD OF THE INVENTION

This invention relates generally to a latch apparatus for a portable electronic device, and more particularly, to a latch apparatus having an actuator portion and a pin portion where the pin portion is biased to fit into an opening to securely fix the portable electronic device to a device mount.

### BACKGROUND OF THE INVENTION

A navigation system performs travel guidance for enabling a user to easily and quickly reach the selected destination. A typical example is a vehicle navigation system where a vehicle is equipped with a navigation function to guide a driver to a destination through a calculated route. In recent years, the use of both mobile media and navigation systems in a vehicle has become increasingly more common. Because of data storage requirements, such systems were initially somewhat bulky and required that the systems be permanently installed in the vehicle. However, more recently developed devices are sufficiently compact to allow them to be personally portable and be temporarily mounted within the vehicle. This gives the user the option to use the device both inside and outside of the vehicle.

In addition to decreasing their size, newer devices have begun to integrate various features, so that a single device can perform several different functions. For example, such a multi-function device may not only be able to display video images, but it may also be capable of displaying map images for performing navigational functions. Namely, such a multi-function device may be able to calculate an optimum route to a destination and perform a guidance operation along the calculated route. The user therefore must be able to see the images on the display device for various purposes even when the device is mounted on the vehicle.

A vehicle sometimes must pass through a bumpy road and can be susceptible to shocks and vibrations due to the road condition. Even under such conditions, the display device (portable device) must be secured to the vehicle to prevent it from falling down. The display device must also be easily attached to or detached from the vehicle so that a user is able use the display device in an in-vehicle mode or to carry the display device in a portable mode.

Therefore, a need exists for an apparatus which, while the display device is used in a vehicle, will secure the display device in a fixed position and prevent displacement due to bumps or other such forces, but at the same time allows the display device to be easily installed and removed from a device mount.

### SUMMARY OF THE INVENTION

It is, therefore, an object of the present invention to provide a latch apparatus that can securely mount a display device to a device mount.

It is another object of the present invention to provide a latch apparatus which is able to sufficiently withstand the forces that derive from the vehicle's vibrations and shocks while allowing easy detachment as needed.

Still another object of the present invention is to provide a portable display device and a device mount where the device mount is fit to the vehicle to receive the portable display device therein such that a navigation antenna of the portable display device is guaranteed to be in an operational condition when the portable display device is securely fixed to the device mount.

In at least one embodiment, the latch apparatus includes a pin with a ramp that can make contact to a ramp of an actuator, which allow the display device to be easily secured into the device mount by a simple sliding action, but which securely holds the display device and prevents any unintentional separation of the display device from the device mount. The latch apparatus further has a retractable pin or pins which so secure the display device in the device mount and which can be retracted by a simple operation of a user to allow the display device to be removed from the device mount.

In such embodiments, the latch apparatus may operate with a stopper that is positioned on the device mount, where the stopper prevents the reception of the display device into the device mount when the navigation antenna is in its non-operational position. The pin is biased to one direction such that the pin secures the display device in a normal condition. The pin can be moved to the direction opposite to the biased direction by applying a certain amount of force to the actuator.

According to the present invention, the latch apparatus has an opening into which the pin is inserted to secure the display device in the device mount. The actuator applies force to release the pin to remove the display device from the device mount. Both the actuator and the pin have ramps that are designed to make contact with each other and slide as force is exerted to the actuator. Due to the ramps, the pin moves to withdraw from the opening of the display device as force is applied to the actuator. Biasing means maintains the position of the pin such that the pin keeps engaging with the opening thereby securely holding the display device in the device mount unless the actuator is pressed for releasing the pin.

Thus, the latch apparatus can securely mount the display device to the device mount and sufficiently withstands the forces that derive from the vehicle's vibrations and shocks while allowing easy detachment as needed. Further, the device mount is fit to the vehicle to receive the portable display device therein such that the navigation antenna of the portable display device is in the operational condition when the portable display device is securely fixed to the device mount.

### BRIEF DESCRIPTION OF THE DRAWINGS

FIG. 1A is a perspective view in part showing a back portion of the display device and a front portion of the device mount, and generally showing the display control apparatus in accordance with at least one embodiment of the present invention.

FIG. 1B is a perspective view in part showing a front portion of the display device and a front portion of the device mount, and generally showing the display control apparatus in accordance with at least one embodiment of the present invention.

FIG. 1C is a perspective view showing in part the display device and the device mount in a typical manner of installation in a vehicle in accordance with at least one embodiment of the present invention.

FIG. 1D is a side cross-sectional view of the display device and the device mount when the antenna of the display device is opened in accordance with at least one embodiment of the present invention.

FIG. 1E is a side cross-sectional view of the display device which is received by the device mount after the situation of FIG. 1D in accordance with at least one embodiment of the present invention.

FIG. 1F is a side cross-sectional view of the display device and the device mount when the antenna of the display device is closed in accordance with at least one embodiment of the present invention.

FIG. 1G is a side cross-sectional view of the display device which is incompletely received by the device mount after the situation of FIG. 1F in accordance with at least one embodiment of the present invention.

FIG. 2 is a side cross-sectional view of the display device and the mount in accordance with at least one embodiment of the present invention.

FIG. 3 is a schematic block diagram showing an example of electrical connection associated with a device function controller provided in the display device in accordance with at least one embodiment of the present invention.

FIGS. 4A and 4B are side cross-sectional views showing a structural relationship among the latch apparatus, display device and the device mount in accordance with at least one embodiment of the present invention.

FIGS. 5A-5C are side cross-sectional views of the latch apparatus to explain the condition and relationship between the pin and the actuator.

### DETAILED DESCRIPTION OF THE PREFERRED EMBODIMENT

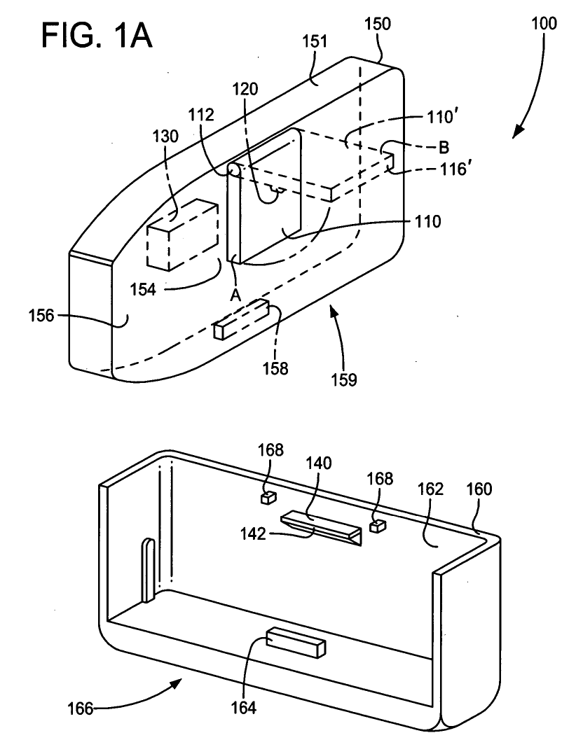

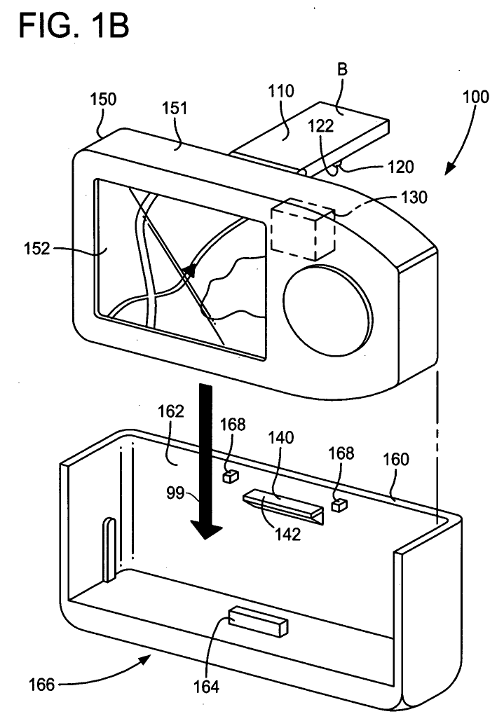

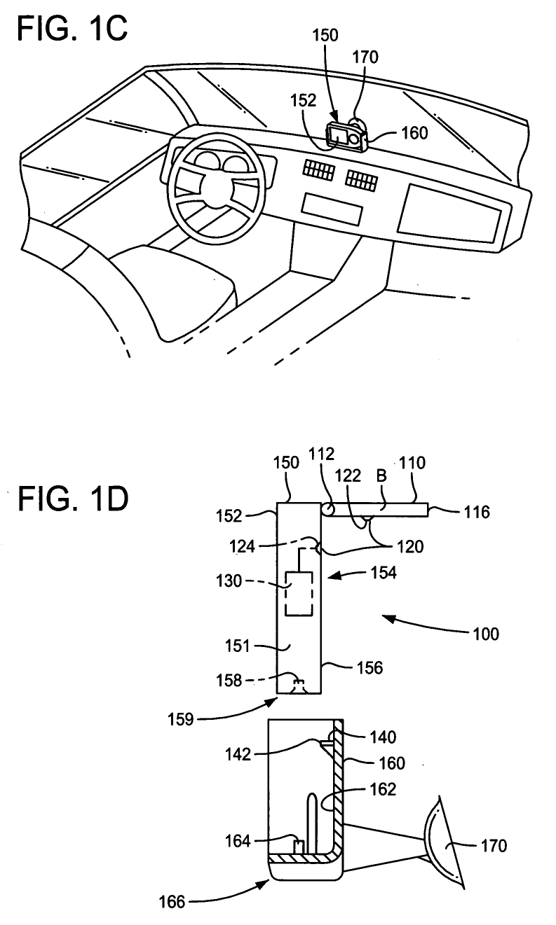

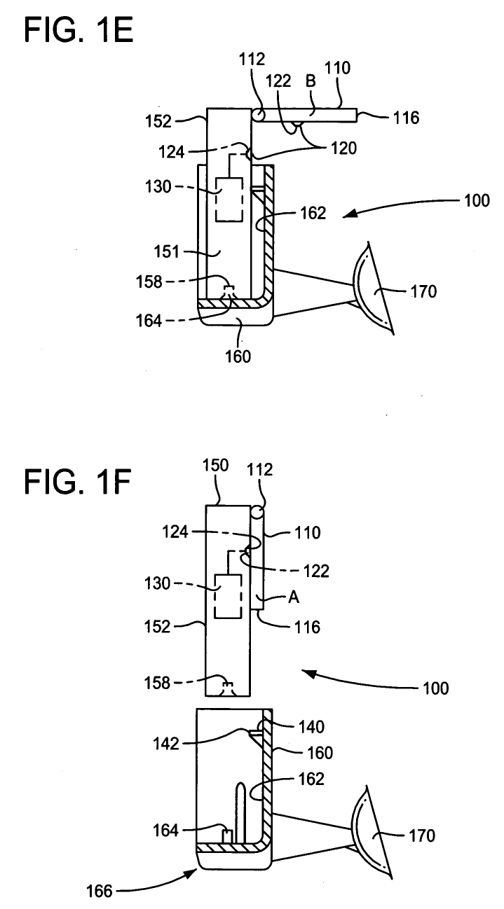

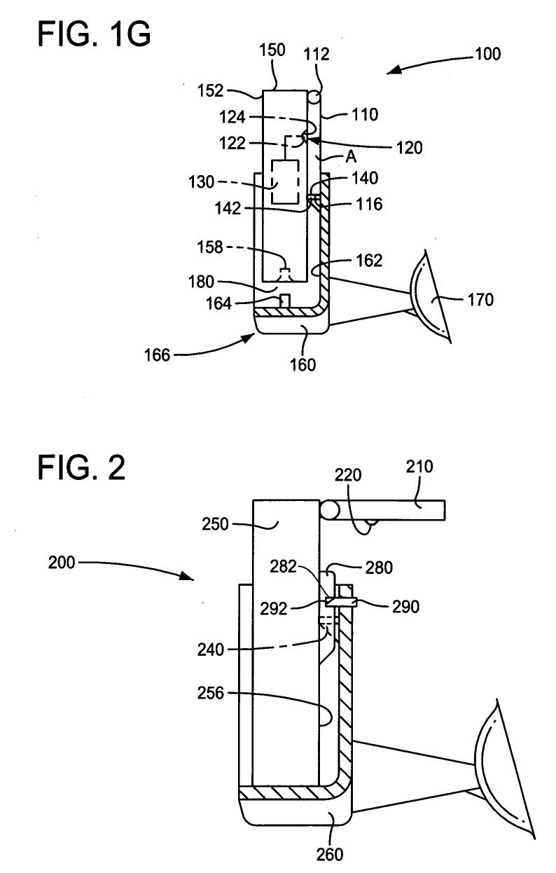

As shown in FIGS. 1A and 1B, in at least one embodiment, a display control apparatus 100 mainly comprises a display device 150 and a device mount or cradle 160. The display device 150 is a portable device that is capable of displaying an image on its screen and generating audible sounds as well as receiving signals by means of a GPS antenna as will be explained further in detail. The device mount (cradle) 160 is designed to receive the display device 150 and establish electrical connection therebetween. The display device 150 includes a navigation (GPS) antenna 110, an antenna positioning sensor 120, a device function controller 130 and a stopper 140.

The display device 150 can, depending on the embodiment, be any of a variety of devices. For example, the display device 150 can be a portable navigation and video display device, having a screen 152 which can display navigation or non-navigational related images, as shown in FIG. 1B. In this example, the screen 152 shows a map image for the navigation function, but movie or picture may be shown on the screen 152 as well.

Such navigational related images can include such items as maps, turn indicators or arrows, addresses, points of interests or POIs, various icons, and the like. Map images can include moving maps marking the location of the user of the device and updating the map as the user's position changes via a GPS or similar navigation system. These maps can be two-dimensional in a top down (plan) view, or three-dimensional, in a perspective view.

Non-navigational images can include recorded video, such as movies, TV programs, or music videos, internet contact (such as web pages, information, etc.) or other images such as menus, set-up and control screens. Non-navigational images can be stored in a memory storage unit of the display device, such as a hard drive, flash memory, or the like. The display device 150 may also function as a digital audio player such as an MP-3 player to reproduce audible sounds such as music, drama, foreign language, etc.

As shown in FIGS. 1A and 1B, the display device 150 includes the navigation antenna 110, the antenna positioning sensor 120 and the device function controller 130. The display device 150 may also include a device electrical connector or interface 158 positioned at a bottom portion 159 of the display device 150. The electrical connector 158 functions to allow electronic signals, power, and the like to be transferred between the display device 150 and the device mount 160. Depending on the embodiment, the electrical connector 158 can have any of a variety of different embodiments, such as either a male or female plug or receptacle. In the example of FIGS. 1A and 1B, the connector 158 is a female receptacle.

Depending on the particular embodiment, the device mount (cradle) 160 can be any of a variety of configurations used to hold or secure the display device 150 in place. The device mount 160 allows for hand-free operations by positioning the display device 150 in a fixed manner such that it is easily viewed by the driver of the vehicle, as shown in FIG. 1C. In certain embodiments, the device mount 160 can be secured to the interior of the vehicle by means such as a suction cup 170, adhesive, fastener, or the like.

As shown in FIGS. 1A-1B and 1D, the device mount 160 is shaped and sized to receive at least a portion of the display device 150 in a sliding motion (downward sliding motion as shown by the arrow 99 in FIG. 1B). In the embodiments, the device mount 160 includes the stopper 140 on the inner wall. The device mount 160 may also include an electrical connector or interface 164 positioned at a bottom portion 166 thereof.

The electrical connector 164 is positioned to be capable of contacting or connecting with the device electrical connector 158. The electrical connector 164 functions to allow electronic signals, power, and the like to be transferred between the device mount 160 and the display device 150 via the device connector 158. Depending on the embodiment, the electrical connector 164 can have any of a variety of different embodiments, such as either a male or female plug or receptacle. In the example of FIGS. 1A-1B and 1D, the connector 164 is a male plug. As shown in FIG. 1E, with the display device 150 received by the device mount 160, the device electrical connector 158 and the electrical connector 164 are in contact, allowing electronic signals to be transmitted therebetween.

As shown in the embodiment of FIGS. 1A-1B and 1D-1E, the navigation (GPS) antenna 110 is a generally square shape, which is a typical shape of an antenna for receiving GPS signals. Of course, other embodiments can have different shapes and relative sizes for the antenna, depending on the types of signals and sensitivity of signals they are designed to receive. The navigation antenna 110 may be, as shown, positioned on a rear portion 154 of the display device 150.

The navigation antenna 110 is mounted to the display device 150 at a hinge 112, which allows the navigation antenna 110 to rotate from a closed or a navigation non-operational position A to an open or navigation operational position B as shown in FIG. 1A. As is shown, the antenna 110 of this embodiment can be positioned in any position between the marked open position B and the closed position A by rotating about the hinge 112.

In certain embodiments, the antenna 110 may be positioned to any of a number of positions further past the above noted open position B. In FIG. 1A, the navigation antenna 110 is shown along with the navigation antenna 110′ depicted in broken lines to show the navigation antenna in an open condition. However, the navigation antenna 110 may further be rotated upwardly or downwardly for better reception of the GPS signals depending on the angle of the display device 150 that is mounted in a vehicle, etc.

The closed position A has the navigation antenna 110 positioned along a back surface 156 of the display device 150. In this position, the navigation antenna 110 is generally out of the way of the user and allows for a more compact device for storage or transportation. When the navigation antenna 110 is in the closed position, the antenna will typically not be properly positioned for receiving signals from orbiting GPS satellites as the body 151 of the display device 150, buildings and other structures outside will block some, or all, of the GPS signals.

Also, in the closed position A, the navigation antenna 110 may not be positioned to avoid E.M.I and/or radiation problems. That is, the internal electronic components of the display device 150 may be capable of transmitting electromagnetic signals and/or other radiation. Such signals and radiation can interfere with the operation of the navigation antenna 110 due to the close proximity of the antenna 110 to these internal components when the antenna 110 is in the closed position A.

For these reasons, with the navigation antenna 110 in the closed position A, in the embodiments of the present invention, the navigation functions of the display device 150 are turned off, set into a standby mode, or otherwise reduced in their operational capacity. Having the navigation functions turned-off, or otherwise reduced, allows the display device 150 to reduce its power consumption and extend life of the battery. The standby mode also allows the additional processor resources for performing other functions such as video processing, etc.

The open position B for the navigation antenna 110 is shown in FIGS. 1A (shown in broken lines), 1B and 1D-1E. As shown in FIG. 1A-1B and 1D-1E, the navigation antenna 110 is positioned out and away from the body 151. This positioning provides a better position for the reception of satellite signals as the navigation antenna 110 is generally positioned so that the signals will be perpendicular, or generally perpendicular, to an upper surface of the antenna 110 without the body 151 being in the way of the satellite signals. The navigation antenna 110 also includes an end 116 positioned generally opposite to the hinge 112.

Since the device mount (cradle) 160 facilitates the use of the display device 150 during operations of a vehicle, and to allow the navigation functions to be employed during vehicle operations, the navigation antenna 110 needs to be in its open position B while the display device 150 is in the device mount 160, as shown in FIG. 1E. Clearly, if the navigation antenna 110 was in its closed position A while the display device 150 is in the device mount 160, then, reception of the satellite signals would be greatly impeded or obstructed by positioning the antenna 110 behind the structures of both the body 151 and the mount 160.

The display control apparatus 100 also includes the antenna positioning sensor 120, as shown in the embodiment of FIGS. 1A-1B and 1D-1G. The antenna position sensor 120 operates to inform the device function controller 130 of the current position of the navigation antenna 110. Then, as further described below, the device function controller 130 sets the operation of the navigation function in accordance with the position of the antenna 110.

The antenna position sensor 120 can be any of a variety of mechanisms depending on the particular embodiment of the display control apparatus 100. Some embodiments include contact switches, micro switches, proximity sensors, magnetic switches, inductance switches, optical indicators, pressure sensors, and the like. As shown, the antenna position sensor 120 includes a tab or pin 122 positioned on the navigation antenna 110 and a switch 124 positioned on the body 151 of the display device 150.

As shown in FIGS. 1D and 1F, as the navigation antenna 110 is moved to the closed position A from the open position B, the tab 122 projects into the body 151 and the switch 124 is activated. The activation of the switch 124 transmits a signal to the device function controller 130 indicating that the antenna is in its closed position. Depending on the condition under which the navigation system is operating, the device function controller 130 can control the range of functions of the display device 150.

More specifically, the device function controller 130 controls either the operation of the navigation functions, the non-navigation image display, both the navigation functions and the non-navigation image display, and/or other aspects of the operation of the display device 150. In certain embodiments, the device function controller 130 will turn-off, place in a stand-by mode or otherwise limit the operation of the GPS receiver when the controller 130 receives a signal or any other indication from the antenna position sensor 120 that the antenna 110 is in the closed position A. Further, in such embodiments, with a signal or other indication that the antenna 110 is in the open position B, the device function controller 130 will place the navigation functions in a full operating mode and prevent or turn-off the display of any non-navigation images or other potentially distracting images.

Referring to FIGS. 1A-1B and 1D-1G, the stopper 140 is positioned on the device mount 160 and operated to require the navigation antenna 110 to be in its open position B when the display device 150 is installed in the device mount 160. FIG. 1G shows that with the navigation antenna 110 in its closed position A, the stopper 140 comes into contact with the end 116 of the antenna 110 and prevents the display device 150 from being fully received by the mount 160. With the navigation antenna 110 in the open position B, as shown in FIG. 1E, the antenna 110 is rotated out of the way of the stopper 140, and the display device 150 is capable of being fully received by the device mount 160.

In the embodiments shown in FIGS. 1A-1B and 1D-1G, the stopper 140 is positioned on a back wall 162 of the device mount 160, such that the stopper 140 is located to contact the end of the closed antenna 110 as the display device 150 is slid into the device mount 160. In other embodiments of the invention, variations to the embodiments described above also possible. These variations can include the size and shape of the navigation antenna 110, the positioning of the antenna 110 on the display device 150, the shape and size of the device mount (cradle) 160, etc.

As a result, the particular size, shape and position of the stopper 140 may vary accordingly. For example, in certain embodiments, the stopper 140 may be one or more pins, tabs, clips or the like, which are located to contact the closed antenna 110. In other examples, the stopper 140 may be shaped or formed to receive only a portion of the navigation antenna 110 as to prevent a complete installation of the display device 150 into the device mount 160 with the antenna in the closed position A.

For the embodiments shown, the stopper 140 includes a contact surface 142, which is sized and positioned to contact the end 116 of the navigation antenna 110, when the antenna 110 is in, or generally in, its closed position A, as shown in FIG. 1G. As shown, because of the contact of the surface 142 and the end 116, the display device 150 is prevented from being completely received by the device mount 160. Thus, the display device 150 is unable to be in place and/or to make contact between the electrical connectors 158 and 164 for electrical communication.

Specifically, as the navigation antenna 110 and the stopper 140 contact each other a gap 180 is formed between the display device 150 and the device mount 160, such that the device 150 is not received by the mount 160. As such, the stopper 140 requires the navigation antenna 110 to be positioned in the opened position, for example the position B, for the display device 150 to be completely received by, and electrically connected to, the device mount 160.

As shown in FIGS. 1A-1B and 2, in the embodiments of the present invention, the device mount (cradle) 160 may also includes clips or tabs (clips 168 in FIGS. 1A and 1B). The clips or tabs 168 function to secure the position of the display device 150 upon its receipt into the device mount 160. Though not shown, the display device 150 may have corresponding notches or grooves in the back that snugly receives the clips 168.

The function of the clips or tabs 168 is explained with reference to the embodiment shown in the side view of FIG. 2 in which reference numerals are renumbered. As shown, the device mount 260 of the display control apparatus 200 has clips 290 that are sprung to be urged outward and include ramps 292 at the ends. The clips 290 and the ramps 292 at the ends allow the display device 250 to slide past the clips 290 as the display device 250 is positioned or slid into the device mount 260.

The clips 290 are received into openings 282 positioned on a structure 280, which extends out from the back 256 of the display device 250. The clips 290 can also include a retraction means (not shown), such as a levered button to move the clips 290 back out of the openings 282. Thus, by operating the retraction means, the display device 250 can be removed from the device mount 260 by a sliding motion (upward sliding motion as shown).

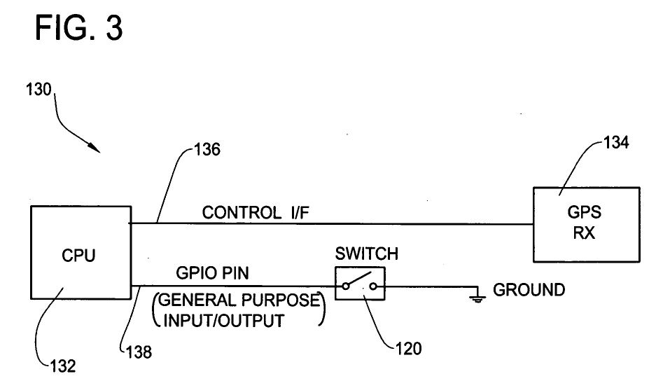

FIG. 3 is a schematic diagram showing an example of arrangement of the device function controller 130. As shown, the device function controller 130 includes a CPU 132, a GPS receiver 134, a control I/F 136, a GPIO (General Purpose Input/Output) pin 138, a switch (antenna positioning sensor) 120, and a ground. The switch 120 is connected between the GPIO pin 138 and the ground and the control IF 136 is positioned between the CPU 132 and the GPS receiver 134. In this manner, the CPU 132 can sense the position of the GPS antenna (not shown) and then send a corresponding command to the GPS receiver 134 to change its operating status (e.g. on, off, standby, etc.).

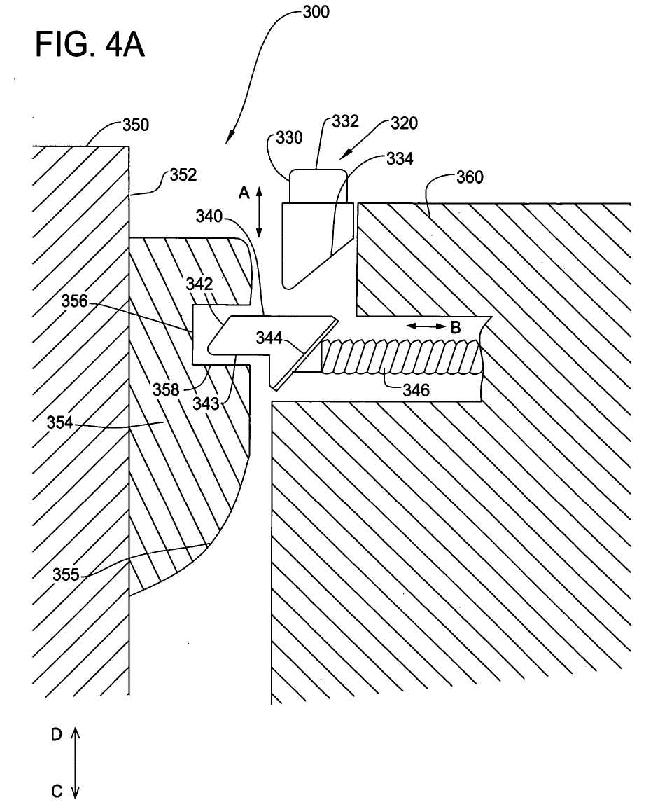

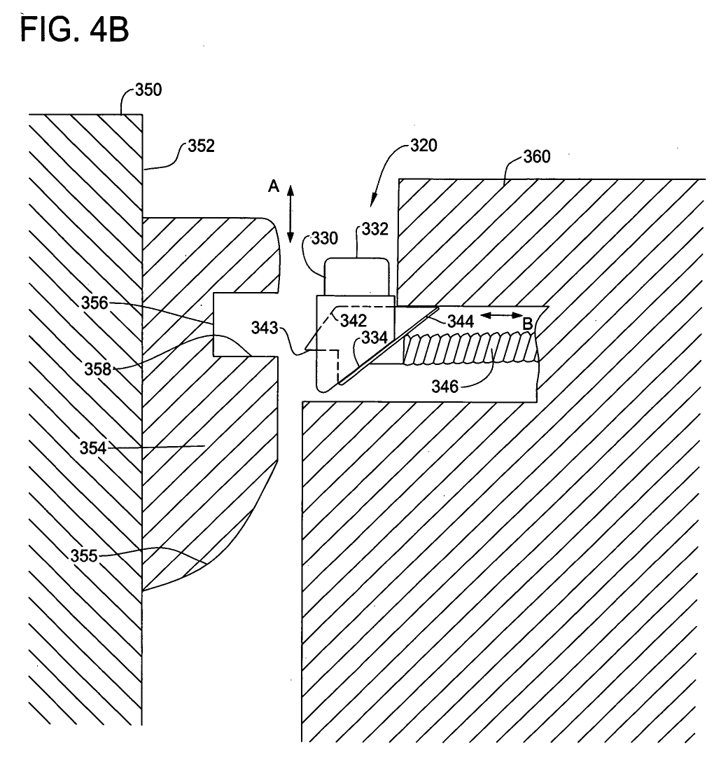

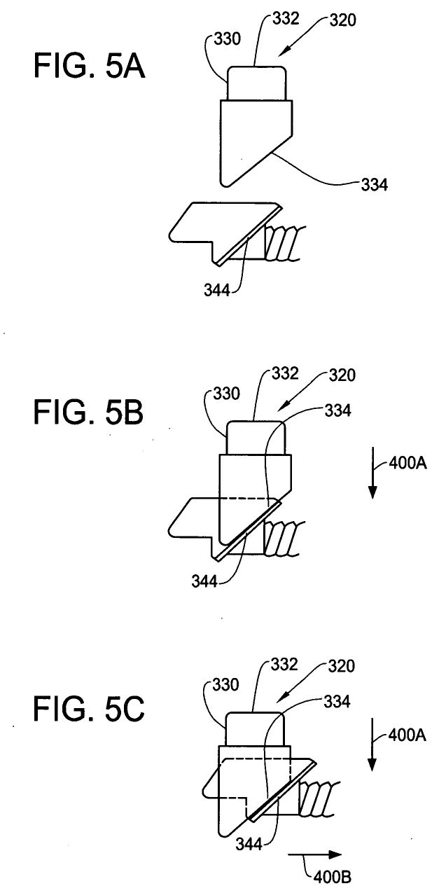

The mechanism of the latch apparatus under the present invention is described with reference to FIGS. 4A-4B and 5A-5C. FIGS. 4A and 4B are side cross-sectional views showing a structural relationship among the latch apparatus, the portable display device and the device mount in accordance with the present invention. FIGS. 5A-5C are side cross-sectional views of the latch apparatus to explain the condition and relationship between the components configuring the latch apparatus.

These drawings show a latch apparatus 300 which, similar to the example of FIG. 2, can secure a portable display device 350 into a device mount 360. As shown, the latch apparatus 300 is generally formed of a latch 320 configured by an actuator 330 and a pin 340, an opening 356 formed on the display device 350 and a biasing means 346 formed on the device mount 360. The actuator 330 is positioned over the pin 340 and is attached to the device mount 360 such that it can move vertically (arrow A) but not horizontally. The pin 340 is attached to the device mount 360 through the biasing means 346 such that it can elastically move in the horizontal direction (arrow B) but not in the vertical direction.

The cross-sectional view of FIG. 4A shows the condition where the actuator 330 is not pressed downward and the pin 340 is engaged to the opening 356 formed on the display device 35 to secure the display device 350 to the device mount (cradle) 360, i.e, the pin 340 is in an engaged position. As will be explained in more detail later, FIG. 4B shows the condition where the actuator 330 is pressed downward to disengage the pin 340 from the opening 356 such that the display device 350 can be removed from the device mount 360, i.e, the pin 340 is in a disengaged position.

In the embodiment shown in FIGS. 4A and 4B, the latch 320 is positioned between the display device 350 and the device mount 360. As with the other embodiments set forth herein, the display device 350 is received into the device mount 360 by a downward sliding movement in the direction of the arrow C and removed from the mount 360 by a sliding motion in the direction of the arrow D.

In the mechanism of the latch 320, the actuator 330 can be slid up and down, as shown by the arrows A to engage the pin 340. As the pin 340 is free from the actuator 330, it slides in the leftward direction shown by the arrows B to fit in the opening 356 of the display device 350. With the actuator 330 depressed, the pin 340 slides back into in the rightward direction shown by the arrow B. In other words, when the actuator 320 is pressed, the pin 340 is moved back away from the display device 350, allowing the display device 350 to be removed from the device mount 360.

The actuator 330 includes a button or contact pad 332 on the top and a ramped surface or actuator ramp 334 on the bottom. The button 332 is shaped and positioned to receive the finger of a user to depress the actuator 330 downwardly. The actuator ramp 334 is angled and positioned to contact a ramped surface of the pin 340 to cause the pin 340 to be moved out from the display device 350.

The pin 340 includes a pin ramp 342, a retention surface 343, an actuator contact ramp 344 and is connected to the biasing means or spring 346. The pin ramp 342 operates to move the pin 340 backwards (right direction) as the display device 350 is slid into the device mount 360. That is, the pin 340 is pressed toward the device mount 360 when the ramp surface 355 of the display device 350 contacts and slides on the pin ramp 342. The slant angle of the pin ramp 342 and the ramp surface 355 allows smooth entry of the display device 350 into the device mount 360.

The ramp surface 355 is part of a structure 354 which is formed on the back portion 352 of the display device 350. The structure 354 also includes the opening 356 which receives the pin 340 as the display device 350 is fully inserted in the device mount 360. The opening 356 further includes a retention surface 358, which contacts the retention surface 343 of the pin 340 when the display device 350 attempts to be removed without the pin 340 being recessed, thereby preventing the removal of the display device 350 from the device mount 360.

The actuator contact ramp 344 is positioned to received the actuator ramp 334 of the actuator 320 as the actuator is depressed, causing the pin 340 to move backwards (right direction). The pin 340 is biased by the spring 346 toward the left direction, causing the pin 340 to be maintained in the opening 356 until the actuator 330 is depressed. Due to the ramps 334 and 344, the spring 346 also causes the actuator 340 to be biased upward, allowing the user easier access to the actuator 340.

FIG. 4B shows the latch 320 with the actuator 330 depressed and the pin 340 moved backward and out of the opening 356. In this condition, the display device 350 can be slid out from the device mount 360. Thus, unless, the actuator 330 is pressed downward with a certain amount of force that overcomes the biasing force produced by the spring 346, the display device 350 is securely fixed to the device mount (cradle) 360. Although spring 340 is used as a biasing means such as synthetic rubber may also be used to exert certain amount of force to push out the pin 340.

In at least one embodiment of the present invention, at least one of the surfaces of the actuator ramp 334 and/or the actuator contact ramp 344 are rough. In some embodiments only one of these surfaces are rough while the other is smooth. This arrangement of rough and smooth surfaces provides for an improves operation of the latch 320 by preventing biding, sticking or similar problems and can reduce the wear on components and the ramped surfaces.

FIGS. 5A-5C are side views showing the conditions and operational steps of the latch 320 of the latch apparatus 300 to secure or release the display device 350. FIG. 5A is a side view wherein the actuator 330 and the pin 340 are not in contact. As can be seen in the drawing, the angles of the actuator ramp 334 of the actuator 330 and the actuator contact ramp 344 of the pin portion 340 are substantially the same so that when they are in contact, the surface of the actuator ramp 334 and surface of the actuator contact ramp 344 substantially contact with each other.

FIG. 5B shows the condition where the actuator 330 and the pin portion 340 begin to contact with one another but the actuator is not further pressed downward. The direction of the downward force is shown by the arrow 400A. Because the pin 340 is biased toward the left by the spring 346, certain amount of force is required to further press down the actuator 330.

As the actuator 330 is further pressed downward, the force applied downward is converted to the horizontal motion of the pin 340 as shown in FIG. 5C. As the arrow 400B indicates, the pin 340 is moved horizontally to the right because the ramps 334 and 344 convert the direction of the force in the direction of the arrow 400A (vertical) to the direction of the arrow 400B (horizontal). Thus, the pin 340 is recessed to the device mount 360 and the display device 350 can be slid out from the device mount 360 as the pin 340 disengaged from the opening 356.

As has been described above, according to the present invention, the latch apparatus has an opening into which the pin is inserted to secure the display device in the device mount. The actuator applies force to release the pin to remove the display device from the device mount. Both the actuator and the pin have ramps that are designed to make contact with each other and slide as force is exerted to the actuator. Due to the ramps, the pin moves to withdraw from the opening of the display device as force is applied to the actuator. Biasing means maintains the position of the pin such that the pin keeps engaging with the opening thereby securely holding the display device in the device mount unless the actuator is pressed for releasing the pin.

Thus, the latch apparatus can securely mount the display device to the device mount and sufficiently withstands the forces that derive from the vehicle's vibrations and shocks while allowing easy detachment as needed. Further, the device mount is fit to the vehicle to receive the portable display device therein such that the navigation antenna of the portable display device is in the operational condition when the portable display device is securely fixed to the device mount.

Although the invention is described herein with reference to the preferred embodiment, one skilled in the art will readily appreciate that various modifications and variations may be made without departing from the spirit and scope of the present invention. Such modifications and variations are considered to be within the purview and scope of the appended claims and their equivalents.

What is claimed is:

1. A latch apparatus positioned between a display device and a device mount wherein the display device is slidably inserted in the device mount, comprising:
a pin having a pin ramp and an actuator contact ramp, the pin being connected to a biasing means that applies force to move the pin toward an opening formed on the display device, one end of the biasing means being attached to the device mount; and
an actuator having an actuator ramp, the actuator ramp contacting the actuator contact ramp of the pin to cause the pin to retract from the opening formed on the display device when the actuator is pressed.

2. A latch apparatus as defined in claim 1, wherein the pin is moved to either an engaged position where the pin fits in the opening of the display device thereby attaching the display device to the device mount or a disengaged position where the pin retrieves from the opening, wherein the biasing means urges the pin to the engaged position and the actuator urges the pin to the disengaged potion.

3. A latch apparatus as defined in claim 1, wherein the actuator positioned over the pin so that the actuator ramp and the actuator contact ramp contact with one another when the actuator is moved downwardly.

4. A latch apparatus as defined in claim 1, wherein the pin ramp is formed at an end of the pin to allow a surface of the display device slides on the pin ramp when the display device is inserted in the device mount.

5. A latch apparatus as defined in claim 4, wherein the pin is horizontally biased toward a direction opposite to the device mount thereby allowing the pin ramp to enter the opening of the display device when positions of the opening and the pin ramp match with one another.

6. A latch apparatus as defined in claim 5, wherein the actuator positioned over the pin so that the actuator ramp and the actuator contact ramp contact with one another when the actuator is pressed down in a direction perpendicular to the horizontal bias of the pin, and wherein the pin retracts to a direction opposite to the display device when the actuator is further pressed down.

7. A latch apparatus as defined in claim 1, wherein the actuator ramp on the actuator and the actuator contact ramp on the pin have substantially flat surfaces.

8. A latch apparatus as defined in claim 7, wherein the actuator ramp and the actuator contact ramp are angled such that their surfaces substantially overlap with each other when the actuator is pressed down.

9. A latch apparatus of claim 1, wherein either one of the actuator ramp or the actuator contact ramp has a smooth surface, or both of the actuator ramp and the actuator contact ramp have substantially rough surfaces.

10. A latch apparatus as defined in claim 1, wherein the biasing means is a spring where one end of which is connected to the pin and another end of which is connected to the device mount.

11. A latch apparatus as defined in claim 2, wherein the actuator has a contact pad that protrudes from the device mount to apply force to the actuator by pressing down the contact pad to move the pin to the disengaged position.

12. A navigation system for guiding a user to a destination, comprising;
a display device having a navigation antenna which is movable between an operational position and a non-operational position; an antenna positioning sensor for determining the position of the navigation antenna in either the operational position or the non-operational position; and a device function controller for controlling an operation of the display device;
a device mount that receives the portable display device and established electrical communication with the display device; and
a latch apparatus positioned between the display device and the device mount wherein the latch apparatus includes a pin having a pin ramp and an actuator contact ramp, the pin being connected to a biasing means which is attached to the device mount, and an actuator having an actuator ramp, the actuator ramp contacting the actuator contact ramp of the pin to cause the pin to retract from an opening formed on the display device;
wherein the device function controller is in communication with the antenna positioning sensor such that the device function controller changes functions of the display apparatus depending on the position of the navigation antenna.

13. A navigation system as defined in claim 12, wherein the device mount has a stopper that is configured and positioned to prevent the display device from entering therein when the navigation antenna of the display device is in the non-operational position.

14. A navigation system as defined in claim 12, wherein the navigation antenna is rotatably attached to the display device such that navigation antenna is capable of changing its angle to receive signals.

15. A navigation system as defined in claim 12, wherein the pin is moved to either an engaged position where the pin fits in the opening of the display device thereby attaching the display device to the device mount or a disengaged position where the pin retrieves from the opening, wherein the biasing means urges the pin to the engaged position and the actuator urges the pin to the disengaged potion.

16. A navigation system as defined in claim 12, wherein the actuator positioned over the pin so that the actuator ramp and the actuator contact ramp contact with one another when the actuator is moved downwardly.

17. A navigation system as defined in claim 12, wherein the pin ramp is formed at an end of the pin to allow a surface of the display device slides on a surface of the pin ramp when the display device is inserted in the device mount.

18. A navigation system as defined in claim 17, wherein the pin is horizontally biased toward a direction opposite to the device mount thereby allowing the pin ramp to enter the opening of the display device when positions of the opening and the pin ramp match with one another.

19. A navigation system as defined in claim 18, wherein the actuator positioned over the pin so that the actuator ramp and the actuator contact ramp contact with one another when the actuator is pressed down in a direction perpendicular to the horizontal bias of the pin, and wherein the pin retracts to a direction opposite to the display device when the actuator is further pressed down.

20. A navigation system as defined in claim 1, wherein the biasing means is a spring where one end of which is connected to the pin and another end of which is connected to the device mount.
